(19) United States
(12) Patent Application Publication
(10) Pub. No.: US 2026/0003291 A1
(43) Pub. Date: Jan. 1, 2026

(54) DUV LED ARRAY FOR AN ULTRAVIOLET-OZONE CLEANING SYSTEM

(71) Applicant: KLA Corporation, Milpitas, CA (US)

(72) Inventors: Kira Purvin, Livonia, MI (US); Tara Chan, Ann Arbor, MI (US); Mitchell Faust, Ann Arbor, MI (US); Hongbo Si, Ann Arbor, MI (US); Sylvi Haendel, Milpitas, CA (US)

(21) Appl. No.: 18/902,779

(22) Filed: Sep. 30, 2024

Related U.S. Application Data
(60) Provisional application No. 63/665,696, filed on Jun. 28, 2024.
(60) Provisional application No. 63/665,674, filed on Jun. 28, 2024.

(51) Int. Cl. G03F 7/00; F21K 9/69; F21V 29/503; F21Y 105/16; F21Y 115/10

(52) U.S. Cl. CPC G03F 7/7005; F21K 9/69; F21V 29/503; F21Y 2105/16; F21Y 2115/10

(57) ABSTRACT

An LED array can include a printed circuit board having a plurality of LED dies with a split circuit layout, one or more dome lenses, and a heat exchanger on a side of the circuit board opposite that of the LED dies. The LED array can be positioned in an inspection tool configured to inspect a reticle. Light from the LED array can be used to perform UV-ozone cleaning of the optical element using the light from the LED array.

### CROSS-REFERENCE TO RELATED APPLICATIONS

This application claims priority to the provisional patent applications filed Jun. 28, 2024 and assigned U.S. App. No. 63/665,674 and U.S. App. No. 63/665,696, the disclosures of which are hereby incorporated by reference.

### FIELD OF THE DISCLOSURE

This disclosure relates to light-emitting diodes arrays used in semiconductor manufacturing.

### BACKGROUND OF THE DISCLOSURE

Evolution of the semiconductor manufacturing industry is placing greater demands on yield management and, in particular, on metrology and inspection systems. Critical dimensions continue to shrink, yet the industry needs to decrease time for achieving high-yield, high-value production. Minimizing the total time from detecting a yield problem to fixing it maximizes the return-on-investment for a semiconductor manufacturer.

Fabricating semiconductor devices such as logic and memory devices typically includes processing a substrate such as a semiconductor wafer or other workpieces using a large number of semiconductor fabrication processes to form various features and multiple levels of the semiconductor devices. For example, lithography is a semiconductor fabrication process that involves transferring a pattern from a reticle to a resist arranged on a semiconductor wafer. Additional examples of semiconductor fabrication processes include, but are not limited to, chemical-mechanical polishing (CMP), etching, deposition, and ion implantation. An arrangement of multiple semiconductor devices fabricated on a single semiconductor wafer may be separated into individual semiconductor devices.

Inspection processes are used at various steps during semiconductor manufacturing to detect defects on wafers to promote higher yield in the manufacturing process and, thus, higher profits. Inspection has always been an important part of fabricating semiconductor devices such as integrated circuits (ICs). However, as the dimensions of semiconductor devices decrease, inspection becomes even more important to the successful manufacture of acceptable semiconductor devices because smaller defects can cause the devices to fail. For instance, as the dimensions of semiconductor devices decrease, detection of defects of decreasing size has become necessary because even relatively small defects may cause unwanted aberrations in the semiconductor devices.

As design rules shrink, however, semiconductor manufacturing processes may be operating closer to the limitation on the performance capability of the processes. In addition, smaller defects can have an impact on the electrical parameters of the device as the design rules shrink, which drives more sensitive inspections. As design rules shrink, the population of potentially yield-relevant defects detected by inspection grows dramatically, and the population of nuisance defects detected by inspection also increases dramatically. Therefore, more defects may be detected on the wafers, and correcting the processes to eliminate all of the defects may be difficult and expensive. Determining which of the defects actually have an effect on the electrical parameters of the devices and the yield may allow process control methods to be focused on those defects while largely ignoring others. Furthermore, at smaller design rules, process-induced failures, in some cases, tend to be systematic. That is, process-induced failures tend to fail at predetermined design patterns often repeated many times within the design. Elimination of spatially-systematic, electrically-relevant defects can have an impact on yield.

As the demand for lithography-based device structures having ever-smaller features continues to increase, the need for improved illumination sources used for lithography and inspection of the associated reticles that lithographically print these devices continues to grow. One such illumination source, used in lithography and inspection systems, is an extreme ultraviolet (EUV) light source. While shifting the scanner wavelength to EUV has enabled printing of the smaller pattern features required for ≤5 nm design node chips, it has also added complexity to the equipment, reticles, photoresists, and other infrastructure required to support EUV lithography. New defect mechanisms and tighter patterning and overlay requirements have driven the need for intensive process control strategies as EUV is adopted. With EUV now being used for production of logic chips and in DRAM manufacturing, process control systems are being used to monitor and control many aspects of EUV lithography. EUV process control includes validating the state of EUV reticles.

Reticles, also known as photomasks or masks, contain the pattern information for features printed on wafers. Within a EUV scanner, EUV light reflects from the reticle surface, transferring the pattern from the reticle to the wafer surface. If there is a defect on a reticle, it can potentially print in every chip on the wafer, creating what is called a repeating defect. A repeating pattern error that kills the chips can be catastrophic to yield. To understand reticle quality, a reticle inspection system finds the defects that can cause this impact.

In an inspection system using EUV, maintaining the environment cleanliness can help sustain the mirror reflectivity and the overall EUV photon budget. However, contaminants that tend to foul the vacuum environment cannot be completely removed from the system. Such is the case, for example, when components of the EUV system like adhesives, actuators, and cables contain unavoidable contamination sources. As a result, the EUV optics within the vacuum chamber are exposed to a partial pressure of contaminants, such as hydrocarbons and gas phase H₂O. These contaminants, when exposed to the EUV radiation within the tool, will lead to the growth of carbon and/or oxides on optical surfaces of the system, such as mirrors. In the case of mirrors, the contamination will cause a reflectivity drop and a phase change in the light incident upon the mirror. Both effects, if unchecked, will cause a degradation of the optics over time, leading to a failure of the optical system.

Even with a multi-layer coating technology, each EUV mirror at normal or near normal incidence angle will likely only reflect some of the light. This reflectivity will be lowered by carbon deposition on the optic surfaces caused by the interaction of volatile organic contamination (VOC) with the energetic EUV photons as well as other wavelengths. For example, in an EUV system, vacuum-ultraviolet/ultraviolet (VUV/UV) photons with wavelengths below 300 nm may also be present in the imaging light and cause contaminate deposition.

A method of cleaning deposited carbon includes exposure of a mirror surface to UV light in the presence of ozone molecules. The carbon removal rate is generally proportional to the UV irradiance. Improved systems and techniques are still needed to clean optical elements and ensure proper performance of inspection systems.

### BRIEF SUMMARY OF THE DISCLOSURE

An LED array is provided in a first embodiment. The LED array includes a printed circuit board having a plurality of LED dies, at least one dome lens disposed over one or more of the LED dies, and a heat exchanger disposed on a side of the circuit board opposite that of the LED dies. The LED dies have a split circuit layout.

The LED array can include a plurality of the dome lenses. Each of the LED dies can have a dome lens disposed thereon.

The LED dies may be arranged in a 5×5 array. In an instance, the LED dies are arranged in 2×5 portion and 3×5 portion with the split circuit thereby adjusting irradiance for a geometry of a chamber environment and an incident angle of the LED dies relative to an optical surface that receives light from the LED dies.

The LED dies can generate UV radiation.

The dome lens can be a 60-degree dome lens.

A system is provided in a second embodiment. The system includes an inspection tool configured to inspect a reticle and an LED array. The LED array includes a printed circuit board having a plurality of LED dies, at least one dome lens disposed over one or more of the LED dies, and a heat exchanger disposed on a side of the circuit board opposite that of the LED dies. The LED dies have a split circuit layout.

The LED array can include a plurality of the dome lenses. Each of the LED dies can have a dome lens disposed thereon.

The LED dies may be arranged in a 5×5 array. In an instance, the LED dies are arranged in 2×5 portion and 3×5 portion with the split circuit thereby adjusting irradiance for a geometry of a chamber environment of the inspection tool and an incident angle of the LED dies relative to an optical surface that receives light from the LED dies in the inspection tool.

The LED dies can generate UV radiation.

The dome lens can be a 60-degree dome lens.

The LED array can be disposed in a chamber of the inspection tool configured to provide UV-ozone cleaning of an optical element. For example, the LED array can be arranged to generate light directed at the optical element.

A method is provided in a third embodiment. The method includes providing an LED array disposed in an inspection tool. The LED array includes a printed circuit board having a plurality of LED dies, at least one dome lens disposed over one or more of the LED dies, and a heat exchanger disposed on a side of the circuit board opposite that of the LED dies. The LED dies have a split circuit layout. Light is generated using the LED array and directed at an optical element in the inspection tool. UV-ozone cleaning of the optical element is performed using the light from the LED. The light may be UV radiation.

The method can include adjusting the light for a geometry of a chamber environment of the inspection tool and an incident angle of the LED dies relative to the optical element using the LED dies arranged in 2×5 portion and 3×5 portion with the split circuit.

### DESCRIPTION OF THE DRAWINGS

For a fuller understanding of the nature and objects of the disclosure, reference should be made to the following detailed description taken in conjunction with the accompanying drawings, in which:

FIG. 1 is a top view of an LED board diagram for an embodiment of the LED array in accordance with the present disclosure;

FIG. 2 is perspective of an LED board diagram for an embodiment of the LED array in accordance with the present disclosure;

FIG. 3 shows an implementation of the LED array of FIG. 2;

FIG. 4 shows an implementation of the system of FIG. 3; and

FIG. 5 shows the grazing angle of the LED array of FIG. 4.

### DETAILED DESCRIPTION OF THE DISCLOSURE

Although claimed subject matter will be described in terms of certain embodiments, other embodiments, including embodiments that do not provide all of the benefits and features set forth herein, are also within the scope of this disclosure. Various structural, logical, process step, and electronic changes may be made without departing from the scope of the disclosure. Accordingly, the scope of the disclosure is defined only by reference to the appended claims.

Embodiments of the LED array disclosed herein provide a dosage of deep ultraviolet (DUV) light on specified surface while using a smaller mechanical envelope. This DUV light can be used as part of a UV-ozone (UVO) cleaning system for optical elements in an inspection system. During UVO cleaning, contaminates (e.g., carbon contaminates on a mirror of an EUV optical system) on an optical element can be irradiated with UV light in the presence of ozone.

UVO cleaning can decontaminate hydrocarbons from, for example, an optical reflective surface. Hydrocarbons tend to be highly absorbing in the DUV region. Cleaning methods that incorporate UV radiation with ozone have been shown to be successful when dealing with hydrocarbons. Since CaF₂ is transparent to the UV light, the UVO cleaning also removes some subsurface contamination without introducing extra damage to the optical surface. Low-energy plasma cleaning containing an Ar and O₂ gas mixture within the vacuum chamber prior to film deposition can further remove both molecular and particulate contamination from the optical surface. The in-situ cleaning process can avoid recontamination issues and improve film adhesion to the substrate surface.

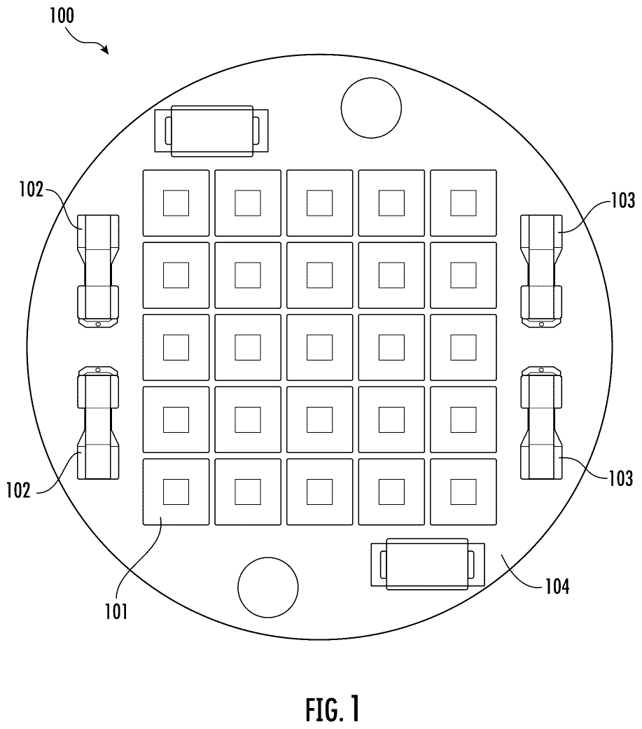

FIG. 1 is a top view of an LED board diagram for an embodiment of the LED array 100. The LED array 100 is illustrated as an array with a split circuit layout. The LED array 100 has LED dies 101 in the 5×5 array. Each of the circuits is in electronic communication with either the electrical connections 102 or electrical connections 103. The electrical connections 102 and electrical connections 103 can be positive or negative electrical connections to power the LEDs. The LED array 100 is fabricated on a printed circuit board 104. The LED dies 101 each may be part of a chip on board module. The LED dies 101 can provide UV radiation. For example, each of the LEDs can be DUV 265 nm wavelength LEDs, though other configurations are possible.

A 5×5 array of LED dies 101 can maximize the number of LED dies 101 in the space. The 5×5 array also can provide a large irradiance (i.e., power per area) within the available space when each of the LED dies 101 has the same output power. However, different arrays are possible. For example, a 2×2, 3×3, or 4×4 array can be used. The configuration of the array may change depending on the available size or other space constraints. However, a larger array may produce more heat, which can require changes to thermal management. In another example, a single LED can be used instead of an array.

The split circuit design of the means that a 2×5 portion of the LED dies 101 are powered independent of the remaining 3×5 portion of the LED dies 101. This can provide a customizable output light distribution and can provide a uniform coverage. The split circuit can be operated using two drivers, which may be AC-to-DC power converters. Two drivers can be used so each of the circuits in the split circuit design can be operated independently. Thus, the two circuits can be operated differently or can provide a more uniform 5×5 array distribution.

The split circuit design can enable changes to the overall irradiance pattern emitted by the LED array 100. Thus, some of the LED dies 101 can be dimmer, which can be driven by geometry because the LED dies 101 are not normal to the optical surface that the LED dies 101 point at. Rather, the optical surface can may receive uniform intensity during cleaning in spite of the difference in angle of the light emitted from the LED dies 101. It was demonstrated that splitting the LED array 100 into a 2×5 portion and 3×5 portion can adjust the irradiance for a geometry of a chamber environment (e.g., relative position of the LED array 100 and the optical element, shape of the chamber, and/or any obstructions in the chamber) and the incident angle of the LED dies 101 relative to the optical surface of the optical element during UVO cleaning. These two portions can operate at different intensities or other light parameters during operation. Use of a 2×5 portion and 3×5 portion provided improved results, but other configurations of the split circuit design are possible. Different configurations can provide different light outputs.

A temperature sensor (not illustrated) may be mounted to a side of the printed circuit board 104 opposite of the LED array 100. The temperature sensor may be used for temperature monitoring. The temperature sensor can serve as a safety interlock and can stop operation or reduce light output above a temperature threshold. The temperature sensor can be in electronic communication with a controller for a cooling system associated with the LED array 100.

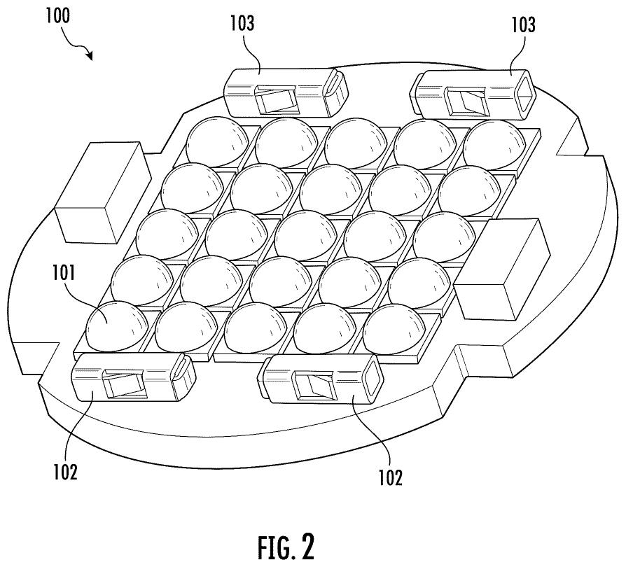

FIG. 2 is perspective of an LED board diagram for an embodiment of the LED array 100. The LED array 100 in FIG. 2 may correspond with the board diagram shown in FIG. 1. Each of the LED dies 101 includes a dome lens. The dome lens can provide broad uniformity over a range of output angles. The dome lens may be, for example, a 60-degree dome lens. The dome lens can be fabricated of fused silica or other materials. The 60-degree dome lens can provide a 60-degree horizontal field of view. While illustrated with individual dome lenses, the LED dies 101 also may be assembled under a single dome lens with a larger output angle.

The power output of the LED array 100 shown in FIGS. 1 and 2 is greater than a single lensed LED or a fiber laser that provides DUV light. For example, the LED array 100 can provide a power output from 1.5 W to 3 W (e.g., 2 W or 2.5 W). The LED array 100 can fit into confined spaces due to its small dimensions. Sizes of the LEDs can balance fitting into the mechanical space of the system and providing high power in a small form factor. Previous illumination systems that fit into these confined spaces had a lower power output. Embodiments of the LED array 100 can outperform similarly-sized illumination systems and provide an enhanced dose. The LED array 100 also avoids transmission fibers used in a fiber-coupled laser. These transmission fibers result in DUV transmission losses.

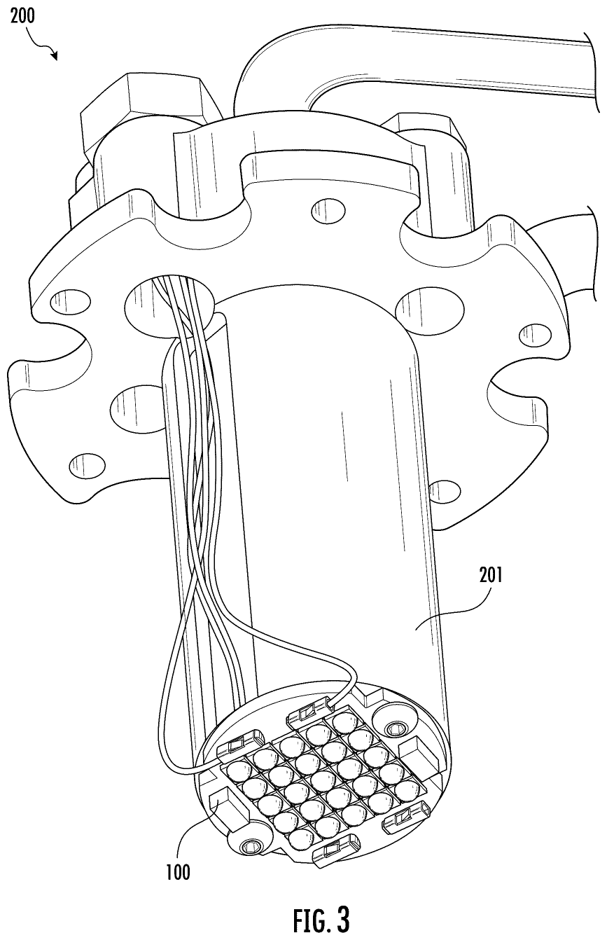

The LED array 100 can be connected to a power supply. The power supply may be connected to the LED array 100 using a shielded cable, which can reduce electrical noise. The cable can pass through a light-tight feedthrough to reduce the risk of UV light escaping the chamber. An exemplary cable is shown in FIG. 3.

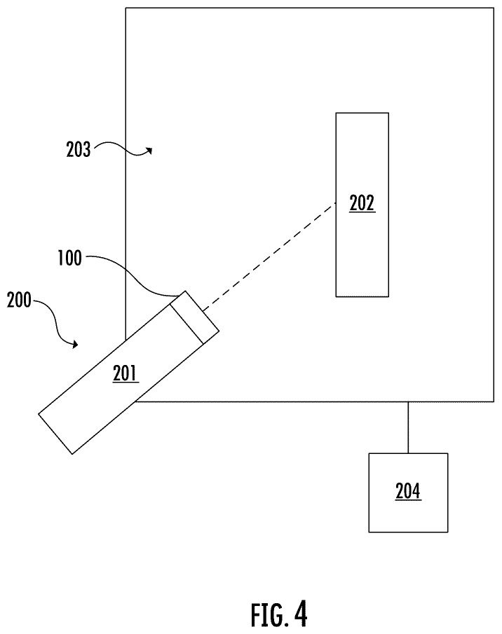

FIG. 3 shows an implementation of the LED array 100, such as that shown in FIGS. 1-2. In FIG. 3, the LED array 100 is implemented on a heat transfer device 201 to form the system 200. The heat transfer device 201 may be, for example, a heat exchanger. As shown in FIG. 4, the system 200 is used to direct light (shown with the dotted line) at an optical element 202 as part of an UVO cleaning system. In an instance, two, three, or more of the systems 200 are used to direct light at the optical element 202. If more than one system 200 is used, then the systems 200 may be arrayed to all illuminated the sensitive surface of the optical component 202. Orientation of the LEDs can be configured to provide uniformity during operation.

The LED dies 101 generate heat during operation. The heat transfer device 201 can remove some or all of this heat created during operation. For example, the heat exchanger may operate up to 200 W.

FIG. 4 is a block diagram of a UV-ozone (UVO) cleaning system 200. An assembly 201 includes an LED array 100 with one or more LEDs dies that can illuminate a sensitive surface of an optical component 202. The optical component 202 may be, for example, a mirror, an optical filter, or a pellicle. The assembly 201 and optical component 202 are in an environment of a chamber 203, which can be a clean, low-pressure environment. For example, the environment can be an ultraclean, vacuum environment. While only one assembly 201 is illustrated, the UVO cleaning system 200 can include two, three, or more assemblies 201. If more than one assembly 201 is used, then the assemblies 201 may be arrayed to all illuminate the sensitive surface of the optical component 203. The assemblies 201 can illuminate the same point, different non-contiguous points, or overlapping points on the sensitive surface. The illumination can be configured to be relatively uniform, which reduces the risk of uneven cleaning on the optical component 202. Non-uniform cleaning can degrade reflectivity or other optical properties of the optical component 202, which may affect the resulting beam.

The assembly 201 can include an LED array 100 with one or more LEDs 111. The LEDs 111 can generate DUV wavelengths directed toward a surface of the optical component 102. The LEDs 111 may be in an array, such as an array with a split circuit design for power distribution optimization. The assembly 201 can have a compact shape and size to reduce size constraints. As described in the embodiments disclosed herein, the assembly 201 also can provide impinging flow liquid cooling for the LEDs 111 using a heat exchanger. The heat exchanger may use re-entrant tubes.

During operation, ozone from the ozone source 204 is injected into the environment of the chamber 203. An optional flow of an inert gas (e.g., N₂) or clean dry air with a coolant (e.g., propylene glycol) can be activated. The inert gas can provide a protective shroud around critical optics (e.g., an LED lens and re-entrant tube window) to minimize degradation from oxidation and moisture. The coolant can be used in the heat exchanger of the assembly 201. The LED or LEDs 111 of the assembly 201 can be activated to illuminate the contaminated surface of the optical component 202 with DUV. This enables cleaning of the optical component 202 via surface decarbonization. After cleaning is complete, the LED or LEDs 111 are turned off. The ozone flow is stopped, and other fluids can be turned off. The environment can be pumped down and restored to a normal operating environment.

The assembly 201 can fit within a limited space while still enabling high-power cleaning. For example, the assembly 201 can fit in a standard KF40 vacuum flange. In another example, the assembly 201 can fit within a chamber port that has a 38 mm diameter and is 62 mm long. The heat exchanger of the assembly 201 can provide compact cooling. The LED or LEDS 111 can cover a large surface area of the optical component 202 relative to their location. Placement of the assembly 201 is flexible because, for example, a re-entrant tube can place the LED light source close to the optical surface that requires cleaning, delivering optical power to the contaminated surface. The re-entrant tube also provides air-vacuum isolation to minimize contamination. The LEDs can be configured to tune the DUV radiation. Also, the main components of the UVO cleaning system 200 are kept outside the chamber 203, which can reduce contamination of the chamber 203.

The re-entrant tube can connect an outside environment to an inside environment and extends into the chamber 203. A bottom of the re-entrant tube can include a window that allows DUV light to enter without adding a DUV light source in the vacuum environment. The re-entrant tube can bring air-side components into vacuum, which can position these components closer to what is being cleaned. This increases the power incident on a cleaned surface while keeping contaminants out.

In an embodiment, a fiber-coupled laser is used instead of the LEDs in the assembly 201. Each assembly 201 may include a lens and fiber subassembly to provide the illumination. The laser source may be positioned outside the chamber 203. The position of the assembly 201 or associated lens can be configured to the fiber's illumination cone. In an embodiment with the fiber-coupled laser, the assembly 201 can use a heat exchanger. In another embodiment with the fiber-coupled laser, the assembly 201 does not use a heat exchanger.

In an embodiment, a linear actuator is used to lower the optical component 202 into the environment of the chamber 203. The assembly 201 can use one or more LEDs or a fiber-coupled laser. This embodiment of the assembly 201 may still use a heat exchanger.

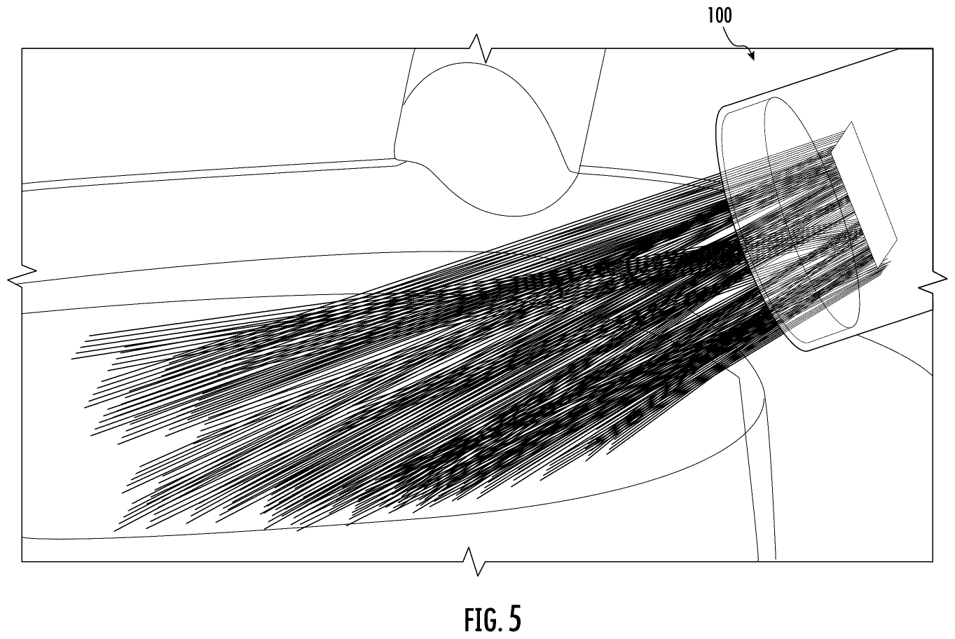

FIG. 5 shows an exemplary grazing angle of the LED array 100 of FIG. 4. The LED array 100 can provide uniformity over a grazing angle. The grazing angle can result from the orientation of the LEDs around the object that is cleaned. The grazing angle in relation to the object that is cleaned can result in non-uniformity. The split circuit can counteract this non-uniformity caused by the grazing angles. For example, a 2×5 portion and 3×5 portion of the LED array 100 with the split circuit was demonstrated to counteract non-uniformity caused by the grazing angles.

The LED array 100 may be used in an inspection tool that performs inspection on a reticle or other workpiece. Inspection techniques described herein may be applied with respect to any suitable type of reticle or photomask. In one example, an EUV lithography process uses an EUV type reticle that is designed to facilitate patterning on a wafer at EUV wavelengths, such as 13.5 nm. An EUV reticle may generally include a substrate, such a low thermal expansion (LTE) or ultra-low expansion (ULE) glass plate, such as fused silica. The substrate is covered with multiple layers of materials to provide moderate reflectance (e.g., 60-70% or more) at the EUV wavelength for performing lithographic exposure at EUV wavelengths. The multilayer (ML) stack serves as a Bragg reflector that maximizes the reflection of EUV radiation while being a poor absorber of the EUV radiation. Reflection generally occurs at interfaces between materials of different indices of refraction with higher differences causing more reflectivity. Although indices of refraction for materials exposed to wavelengths that are extremely low are about equal to 1, reflection can be achieved through use of multiple layers having alternating layers of different refractive indices. The multilayer stack comprises low absorption characteristics so that the impinging radiation is reflected with little loss.

The multiple layers may include a capping layer, such as Ru, to prevent oxidation. In other embodiments, an EUV reticle may include a quartz, antireflective coating (ARC), and other features. A pattern is formed in an absorber layer that is disposed over the multiple layers. The material(s) used for the reticle pattern may be selected to have nearly zero etch bias so as to achieve ultra-fine resolution features.

Besides an EUV type reticle, the terms “reticle” and “photomask” may also include a transparent substrate, such as glass, borosilicate glass, quartz, or fused silica having a layer of opaque material formed thereon. The opaque (or substantially opaque) material may include any suitable material that completely or partially blocks photolithographic light (e.g., deep UV). Example materials include chrome, molybdenum silicide (MoSi), tantalum silicide, tungsten silicide, opaque MoSi on glass (OMOG), etc. A polysilicon film may also be added between the opaque layer and transparent substrate to improve adhesion. A low reflective film, such as molybdenum oxide (MoO₂), tungsten oxide (WO₂), titanium oxide (TiO₂), or chromium oxide (CrO₂) may be formed over the opaque material.

The term reticle may refer to different types of reticles including, but not limited to, a clear-field reticle, a dark-field reticle, a binary reticle, a phase-shift mask (PSM), an alternating PSM, an attenuated or halftone PSM, a ternary attenuated PSM, or a chromeless phase lithography PSM. A clear-field reticle has field or background areas that are transparent, and a dark-field reticle has field or background areas that are opaque. A binary reticle is a reticle having patterned areas that are either transparent or opaque. For example, a photomask made from a transparent fused silica blank with a pattern defined by a chrome metal adsorbing film can be used. Binary reticles are different from phase-shift masks (PSM), one type of which may include films that only partially transmit light, and these reticles may be commonly referred to as halftone or embedded phase-shift masks (EPSMs). If a phase-shifting material is placed on alternating clear spaces of a reticle, the reticle is referred to as an alternating PSM, an ALT PSM, or a Levenson PSM. One type of phase-shifting material that is applied to arbitrary layout patterns is referred to as an attenuated or halftone PSM, which may be fabricated by replacing the opaque material with a partially transmissive or “halftone” film. A ternary attenuated PSM is an attenuated PSM that includes completely opaque features as well.

The defectivity control of the EUV photomasks, which defines the patterns printed on semiconductor wafers or other workpieces, plays a role from a process yield management perspective. However, defect detection has been regarded as one of the risks EUV lithography development due to the lack of an actinic EUV photomask inspector that optically inspects the photomask at the same wavelength as the EUV scanner uses (e.g., 13.5 nm). Electron-beam inspection tools, which potentially can offer a good sensitivity, typically have an inspection throughput that is orders of magnitude slower than what is desired and, therefore, are not usually a practical solution for full mask inspection. Currently, and for the foreseeable future, the inspection of patterned EUV photomasks will rely on the more available, higher throughput inspection tools operating within the deep-UV (DUV) wavelength range (190-260 nm).

While described with respect to an inspection tool and UVO cleaning, the LED array 100 can be used in other systems or for other applications.

Although the present disclosure has been described with respect to one or more particular embodiments, it will be understood that other embodiments of the present disclosure may be made without departing from the scope of the present disclosure. Hence, the present disclosure is deemed limited only by the appended claims and the reasonable interpretation thereof.

What is claimed is:

1. An LED array comprising:
a printed circuit board having a plurality of LED dies, wherein the LED dies have a split circuit layout;
at least one dome lens disposed over one or more of the LED dies; and
a heat exchanger disposed on a side of the circuit board opposite that of the LED dies.

2. The LED array of claim 1, wherein the LED array includes a plurality of the dome lenses, and wherein each of the LED dies has a dome lens disposed thereon.

3. The LED array of claim 1, wherein the LED dies are arranged in a 5×5 array.

4. The LED array of claim 3, wherein the LED dies are arranged in 2×5 portion and 3×5 portion with the split circuit thereby adjusting irradiance for a geometry of a chamber environment and an incident angle of the LED dies relative to an optical surface that receives light from the LED dies.

5. The LED array of claim 1, wherein the LED dies generate UV radiation.

6. The LED array of claim 1, wherein the dome lens is a 60-degree dome lens.

7. A system comprising:
an inspection tool configured to inspect a reticle; and
an LED array disposed in the inspection tool, wherein the LED array includes:
a printed circuit board having a plurality of LED dies, wherein the LED dies have a split circuit layout;
at least one dome lens disposed over one or more of the LED dies; and
a heat exchanger disposed on a side of the circuit board opposite that of the LED dies.

8. The system of claim 7, wherein the LED array includes a plurality of the dome lenses, and wherein each of the LED dies has a dome lens disposed thereon.

9. The system of claim 7, wherein the LED dies are arranged in a 5×5 array.

10. The system of claim 9, wherein the LED dies are arranged in 2×5 portion and 3×5 portion with the split circuit thereby adjusting irradiance for a geometry of a chamber environment of the inspection tool and an incident angle of the LED dies relative to an optical surface that receives light from the LED dies in the inspection tool.

11. The system of claim 7, wherein the LED dies generate UV radiation.

12. The system of claim 7, wherein the dome lens is a 60-degree dome lens.

13. The system of claim 7, wherein the LED array is disposed in a chamber of the inspection tool configured to provide UV-ozone cleaning of an optical element.

14. The system of claim 13, wherein the LED array is arranged to generate light directed at the optical element.

15. A method comprising:
providing an LED array disposed in an inspection tool, wherein the LED array includes:
a printed circuit board having a plurality of LED dies, wherein the LED dies have a split circuit layout;
at least one dome lens disposed over one or more of the LED dies; and
a heat exchanger disposed on a side of the circuit board opposite that of the LED dies;
generating light directed at an optical element in the inspection tool using the LED array; and
performing UV-ozone cleaning of the optical element using the light from the LED array.

16. The method of claim 15, wherein the light is UV radiation.

17. The method of claim 15, further comprising adjusting the light for a geometry of a chamber environment of the inspection tool and an incident angle of the LED dies relative to the optical element using the LED dies arranged in 2×5 portion and 3×5 portion with the split circuit.
